(19) United States
(12) Patent Application Publication
(10) Pub. No.: US 2020/0053917 A1
(43) Pub. Date: Feb. 13, 2020

(54) Cooling Device, Converter Comprising a Cooling Device, and Method for Cooling A Converter

(71) Applicant: Siemens Aktiengesellschaft, München (DE)

(72) Inventors: Vladimir Danov, Erlangen (DE); Volker Müller, Nürnberg (DE)

(73) Assignee: Siemens Aktiengesellschaft, München (DE)

(21) Appl. No.: 16/486,014

(22) PCT Filed: Nov. 7, 2017
(86) PCT No.: PCT/EP2017/078393

§ 371 Date: Aug. 14, 2019

(30) Foreign Application Priority Data
Feb. 15, 2017 (EP) 17156233.3

(51) Int. Cl. H05K 7/20

(52) U.S. Cl. CPC H05K 7/20936; H05K 7/20327; H05K 7/20381; H05K 7/20336

(57) ABSTRACT

Various embodiments include a cooling apparatus for cooling electrical components of a converter comprising: a cooling plate with a first and second cooling region; wherein a first part of the cooling plate includes the first cooling region; and a second part of the cooling plate includes the second cooling region; an evaporative cooler thermally coupled to both the first cooling region and the second cooling region; and a first control element configured to adjust a cooling capacity of the evaporative cooler in relation to at least one of the two cooling regions.

### CROSS-REFERENCE TO RELATED APPLICATIONS

This application is a U.S. National Stage Application of International Application No. PCT/EP2017/078393 filed Nov. 7, 2017, which designates the United States of America, and claims priority to EP Application No. 17156233.3 filed Feb. 15, 2017, the contents of which are hereby incorporated by reference in their entirety.

### TECHNICAL FIELD

The present disclosure relates to cooling apparatus. Various embodiments may include apparatus for cooling electrical components of a converter, converters which comprise a cooling apparatus, and/or methods for cooling electrical components of a converter.

### BACKGROUND

Typically, during operation of a converter, power losses occur which can be traced back to the limited level of efficiency of the electrical components of the converter which are used. The greatest power losses are usually, for instance, exhibited by inverters, balancing resistors, DC link capacitors or additional components, such as rectifiers for example. The electrical components consequently require a constant dissipation of the heat generated by their power loss, in order to ensure the operational reliability of the converter. The prior art distinguishes between air cooling and liquid cooling solutions. Typically, the electrical components to be cooled are screwed to a heat sink, which is in thermal contact with a cooling fluid. Furthermore, the electrical components are fastened to a current-conducting rail, for example by means of a screw connection.

Converters which are cooled by means of a thermosiphon are known. In a thermosiphon, the power loss is used to evaporate a liquid. By evaporating the fluid, heat is extracted from the electrical components, whereby said components are cooled. The steam produced by the evaporation is then supplied to a heat exchanger, which emits the heat to the surrounding environment of the converter by way of condensation of the fluid. The condensed fluid (liquid) is guided back to the electrical components to be cooled, so that a circuit is formed which consists of evaporation and condensation. To support the circuit, for instance against gravitational acceleration, this may have capillary structures for the fluid.

### SUMMARY

The teachings of the present disclosure describe cooling apparatus for cooling electrical components of a converter, providing an improved cooling of the cited electrical components. For example, some embodiments include a cooling apparatus (1) for cooling electrical components of a converter (2), comprising at least one cooling plate (4) with a first and second cooling region (410, 420), wherein the cooling plate (4) is embodied in at least two parts, and a first part of the cooling plate comprises the first cooling region (410) and a second part of the cooling plate (4) the second cooling region (420), wherein the cooling regions (410, 420) are thermally coupled to an evaporative cooling apparatus (6), and the cooling apparatus (1) has at least a first control element (41), by means of which the cooling capacity of the evaporative cooling apparatus (6) of at least one of the cooling regions (410) is able to be controlled.

In some embodiments, it comprises a second control element (42), by means of which the cooling capacity of the evaporative cooling apparatus (6) of the further cooling region (420) is able to be controlled.

In some embodiments, the evaporative cooling apparatus (6) is embodied as a thermal pipe, in particular as a heat pipe or a two-phase thermosiphon.

In some embodiments, the evaporative cooling apparatus (6) has two evaporators for evaporating a cooling fluid, wherein the two evaporators are at least partially embodied by means of the two cooling regions (410, 420) of the cooling plate (4).

In some embodiments, the evaporative cooling apparatus (6) has a pipe system (60) for guiding the cooling fluid, wherein the pipe system (60) has a first line section (61) for the first cooling region (410) and a second line section (62) for the second cooling region (420), wherein the cooling capacity of the first line section (61) is able to be controlled by means of the first control element (41) and/or the cooling capacity of the second line section (62) is able to be controlled by means of the second control element (42).

In some embodiments, at least one of the control elements (41, 42) is embodied as a control valve.

In some embodiments, the cooling plate (4) comprises the line sections (61, 62).

In some embodiments, the line sections (61, 62) are embodied by means of bore holes within the cooling plate (4).

In some embodiments, at least one of the line sections (61, 62) has a plurality of fluid ducts (63) which are fluidically coupled in parallel in relation to the cooling fluid, wherein the fluid ducts (63) extend in parallel with one another spatially.

As another example, some embodiments include a converter (2), characterized in that it comprises at least one cooling apparatus (1) as described above.

In some embodiments, it has a first and second class of electrical components, wherein the first class of electrical components has a higher thermal power loss than the second class of electrical components, and the components of the first class are arranged in the first cooling region (410) and the components of the second class in the second cooling region (420), wherein the first control element (41) can be used to increase the cooling capacity of the evaporative cooling apparatus (6) within the first cooling region (410) compared to the cooling capacity of the evaporative cooling apparatus (6) within the second cooling region (420).

As another example, some embodiments include a method for cooling electrical components of a converter (2), with a converter as described above, characterized in that the cooling capacity of the evaporative cooling apparatus (6) of at least one of the cooling regions (410) is controlled by means of the first control element (41) of the cooling apparatus (1).

In some embodiments, the cooling capacity of the evaporative cooling apparatus (6) of the further cooling region (420) is controlled by means of the second control element (42) of the cooling apparatus (1).

In some embodiments, a control valve is used as the first and/or second control element (41, 42).

### BRIEF DESCRIPTION OF THE DRAWINGS

Further advantages, features and details of the teachings herein will become apparent from the exemplary embodiments described below as well as with reference to the drawings, in which, shown schematically:

FIG. 1 shows a converter with an evaporative cooling apparatus known from the prior art;

FIG. 2 shows a converter with a cooling apparatus incorporating teachings of the present disclosure; and

FIG. 3 shows a further converter with a cooling apparatus incorporating teachings of the present disclosure.

### DETAILED DESCRIPTION

In some embodiments, a cooling apparatus for cooling electrical components of a converter comprises at least one cooling plate with a first and a second cooling region, wherein the cooling regions are thermally coupled to an evaporative cooling apparatus. In some embodiments, the cooling apparatus has at least a first control element, by means of which the cooling capacity of the evaporative cooling apparatus of at least one of the cooling regions is able to be controlled. In some embodiments, all components or structural elements or parts of a converter, which have a thermal power loss during operation of the converter and thus generate heat or waste heat, are considered to be electrical components. In particular, electronic components are considered to be electrical components.

An evaporative cooling apparatus in the context of the present disclosure includes any apparatus which is suitable for cooling or for providing a cooling capacity for the cooling regions by means of a phase transition of a cooling fluid, for instance an evaporation or a boiling of a cooling fluid. The cooling plate or the two cooling regions are provided for arrangement on electrical components to be cooled. The electrical components may typically be divided into two classes, wherein the electrical components of the first class have a comparatively high power loss (high-loss components) and the electrical components of the second class have a comparatively low power loss (low-loss components).

In some embodiments, no movable components, such as pumps for instance, are required for an evaporative cooling apparatus. The evaporative cooling apparatus therefore typically controls or regulates itself. For instance, more steam is generated as the power loss increases. As a result, the pressure loss increases in the lines of the evaporative cooling apparatus. The increased pressure loss induces an increased pressure in the evaporator of the evaporative cooling apparatus, meaning that the evaporation temperature of the cooling fluid rises. The steam temperature which is increased as a result simultaneously increases the density of the steam, meaning that the pressure loss is reduced again. Furthermore, the evaporation temperature of the cooling fluid is dependent upon the condensation temperature of the cooling fluid, which in turn depends upon the temperature of the cooling fluid itself.

In some embodiments, the cooling apparatus has the two cooling regions. In this context, the cooling capacity of at least one of the cooling regions may be controlled by means of the first control element. This results in two cooling regions which may have a different cooling capacity. In other words, this results in the cooling capacity of at least one of the cooling regions being able to be adapted to the power loss of the electrical components arranged in said cooling region. For instance, the first cooling region is provided for electrical components with a high power loss, wherein the cooling capacity of the first cooling region is able to be controlled by means of the control element.

Consequently, the cooling capacity for the high-loss electrical components can be increased by means of the control element. Furthermore, the cooling capacity of the evaporative cooling apparatus may turn out to be lower within the second cooling region compared to the first cooling region. Overall, this means that the cooling of the electrical components of the converter become more efficient by means of the cooling apparatus incorporating teachings of the present disclosure. By means of the cooling apparatus, it therefore becomes possible to control or regulate the cooling capacity of the evaporative cooling apparatus in at least two cooling regions of the cooling plate. As a result, the temperature in at least one of the cooling regions may be controlled and adapted.

In some embodiments, the cooling apparatus comprises a second control element, by means of which the cooling capacity of the evaporative cooling apparatus of the further cooling region can be controlled. In some embodiments, this means that the cooling capacity of the evaporative cooling apparatus can be controlled in the two cooling regions of the cooling apparatus. As a result, the efficiency of the cooling apparatus may be improved. This is therefore the case since, for instance, the first cooling region is provided for high-loss electrical components and the second cooling region for low-loss electrical components, and the respective cooling capacity at the components to be cooled in the two cooling regions is able to be adapted separately from one another. In other words, the cooling capacity within the cooling regions is able to be adapted to the electrical power loss of the electrical components arranged in the cooling regions.

In some embodiments, the evaporative cooling apparatus is embodied as a thermal pipe, in particular as a heat pipe or a two-phase thermosiphon. As a result, the efficiency of the cooling apparatus may be further improved. Typically, a thermal pipe has an evaporator, a condenser and a pipe system for a cooling fluid, which is evaporated within the evaporator, condensed within the condenser and guided by means of the pipe system.

In some embodiments, the evaporative cooling apparatus has two evaporators for evaporating the cooling fluid, wherein the two evaporators are at least partially embodied by means of the two cooling regions of the cooling plate. In other words, the cooling fluid is at least partially brought to evaporation by the electrical components arranged within the two cooling regions. The steam of the cooling fluid is then guided via the pipe system to the condenser of the evaporative cooling apparatus. Within the condenser of the evaporative cooling apparatus, the cooling fluid at least partially condenses and in doing so at least partially emits the heat absorbed by its evaporation, which at least partially corresponds to the power loss of the electrical components, at least partially to the surrounding environment. The condensed cooling fluid is then guided back to the two cooling regions of the cooling plate by means of the pipe system. In this context, the evaporative cooling apparatus has two evaporators and a common condenser. Furthermore, the two evaporators and the common condenser may be arranged within a common pipe system, wherein the two evaporators are connected in parallel in relation to the mass flow of the cooling fluid.

In this context, the evaporation temperature of the cooling fluid, for instance, may be controlled or regulated by means of a bimetal regulation within the line section of the steam. In some embodiments, the evaporative cooling apparatus has a pipe system for guiding the cooling fluid, wherein the pipe system has a first line section for the first cooling region and a second line section for the second cooling region. Furthermore, in this context, the cooling capacity of the first line section is able to be controlled by means of the first control element and/or the cooling capacity of the second line section is able to be controlled by means of the second control element.

In other words, the cooling regions of the cooling apparatus are assigned different line sections of the pipe system. By means of the first and/or second control element, the cooling capacity of the line sections are, for instance, able to be controlled by adapting the mass flow of the cooling fluid and/or the pressure of the cooling fluid. In doing so, the first line section is embodied to guide the cooling fluid to the first cooling region and the second line section to guide the cooling fluid to the second cooling region of the cooling apparatus. Within the cooling regions, the cooling fluid then at least partially evaporates within the line sections due to the heat generated in the cooling regions by means of the electrical components. In this context, the line sections are typically connected in parallel in relation to the mass flow of the cooling fluid.

In some embodiments, at least one of the control elements is embodied as a control valve. In some embodiments, both control elements, i.e. the first and the second control element, are each embodied as a control valve. In other words, the pipe system is divided into the first and second line section, wherein one control valve is provided for each line section. As a result, it becomes possible to control the temperature or the cooling capacity within the cooling regions. For instance, the pressure loss within the line section, which is provided for lower-loss components, is increased, whereby less cooling fluid flows through the cited line section and thus the cooling capacity is reduced. In other words, in this context the control valve is throttled. As a result, the temperature within the cooling region assigned to the line section tends to be increased. If both control valves are throttled, then the temperature rises within the cooling regions, since the overall pressure loss of the evaporative cooling apparatus rises. If an operating point of the evaporative cooling apparatus has been configured while taking into consideration a partial throttling of the control valves, then the evaporation temperature of the cooling fluid drops when the control valves are opened.

In some embodiments, the cooling plate comprises the line sections. As a result, the thermal coupling between the cooling plate and the line sections, and thus the thermal efficiency of the cooling apparatus, may be improved.

In some embodiments, the line sections are embodied by means of bore holes within the cooling plate. As a result, the thermal coupling between the cooling plate and the line sections or between the cooling plate and the cooling fluid within the line sections may be further improved.

In some embodiments, at least one of the line sections has a plurality of fluid ducts which are fluidically coupled in parallel in relation to the cooling fluid, wherein the fluid ducts extend in parallel with one another spatially. In this context, the fluid ducts may be embodied by means of bore holes within the cooling plate. The cooling fluid may be distributed by the fluid ducts over a large area within the cooling regions. As a result, a particularly large amount of heat can be dissipated.

Furthermore, electrical components of a converter are typically arranged at various geodetic heights. Since the pressure of the cooling fluid changes along the cooling plate, its evaporation temperature also changes along the cooling plate. In addition, due to the thermal energy transferred to the cooling fluid, the temperature thereof increases along the cooling plate. To create as homogeneous a temperature and pressure distribution as possible, some embodiments include a plurality of fluid ducts. Due to the plurality of fluid ducts, in particular the fluid ducts which are fluidically coupled in parallel, the mass flow of the cooling fluid can be controlled actively and the temperature can be kept approximately constant along the cooling plate.

In some embodiments, the cooling plate is embodied in at least two parts, wherein a first part of the cooling plate comprises the first cooling region and a second part of the cooling plate the second cooling region. A modular design may be produced as a result. Furthermore, the thermal insulation between the first cooling region and the second cooling region may be improved.

In some embodiments, a converter comprises a cooling apparatus as described above or one of its embodiments. The converter incorporating the teachings of the present disclosure has similar and equivalent advantages to the cooling apparatus already mentioned. In some embodiments, the converter has a first and second class of electrical components, wherein the first class of electrical components has a higher thermal power loss than the second class of electrical components and the components of the first class are arranged in the first cooling region and the components of the second class in the second cooling region, wherein the first control element can be used to increase the cooling capacity of the evaporative cooling apparatus within the first cooling region compared to the cooling capacity of the evaporative cooling apparatus within the second cooling region.

In other words, the first cooling region of the cooling apparatus is provided for the high-loss electrical components, for instance bipolar transistors with insulated gate bipolar transistors (IGBTs). The second cooling region of the cooling apparatus is provided for lower-loss electrical components, for instance condensers. As a result, the cooling capacity may be adapted to the power loss of the electrical components of the converter to the greatest extent possible, and is thus optimized. As a result, the energy efficiency of the converter is improved.

In this context, the cooling fluid or the condensation thereof is typically distributed to both cooling regions via the pipe system. In the prior art, the boiling temperature of the cooling fluid within the cooling region provided for the low-loss components is influenced and determined by the high-loss components via the fluid ducts, which communicate in parallel and are assigned to the cooling regions. To prevent this influence, at least the first control element, by means of which the cooling capacity within the cooling regions is able to be controlled separately from one another.

In some embodiments, a method for cooling electrical components of a converter incorporating the teachings of the present disclosure is characterized in that the cooling capacity of the evaporative cooling apparatus of at least one of the cooling regions is controlled by means of the first control element of the cooling apparatus. The methods described herein have similar and equivalent advantages to the cooling apparatus and the converter described herein.

In some embodiments, a control valve is used as the first and/or second control element. Elements which are similar, equivalent or have a similar effect can be provided with the same reference characters in the figures.

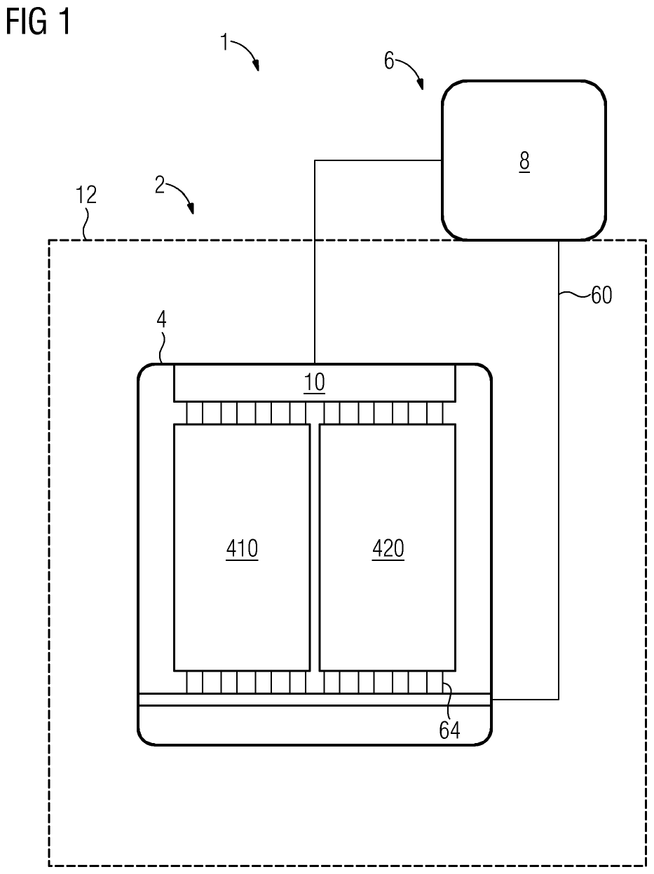

FIG. 1 shows an outline of the converter 2, which has a cooling apparatus 1 known in the prior art. In this context, the cooling apparatus 1 is embodied as an evaporative cooling apparatus 6. The evaporative cooling apparatus 6 comprises a pipe system 60 and a condenser 8. Arranged within a cabinet 12 of the converter 2 is a cooling plate 4. The cooling plate 4 is provided for the arrangement of electrical components as well as the cooling thereof. To this end, the cooling plate 4 is thermally coupled to the pipe system 60 of the evaporative cooling apparatus 6. Furthermore, the cooling plate 4 has a plurality of fluid ducts 64, which are fluidically connected in parallel in relation to a cooling fluid within the pipe system 60, for cooling the electrical components.

The cooling apparatus 1 known from the prior art has two cooling regions 410, 420, within which electrical components with different power losses are arranged. Arranged within the first cooling region 410 are, for instance, high-loss electrical components, in particular IGBTs. Arranged within the second cooling region 420 are then comparatively low-loss electrical components, for instance condensers. The fluid ducts 64, which are thermally coupled to the cooling regions 410, 420 and extend through these, are provided to cool the cooling regions 410, 420.

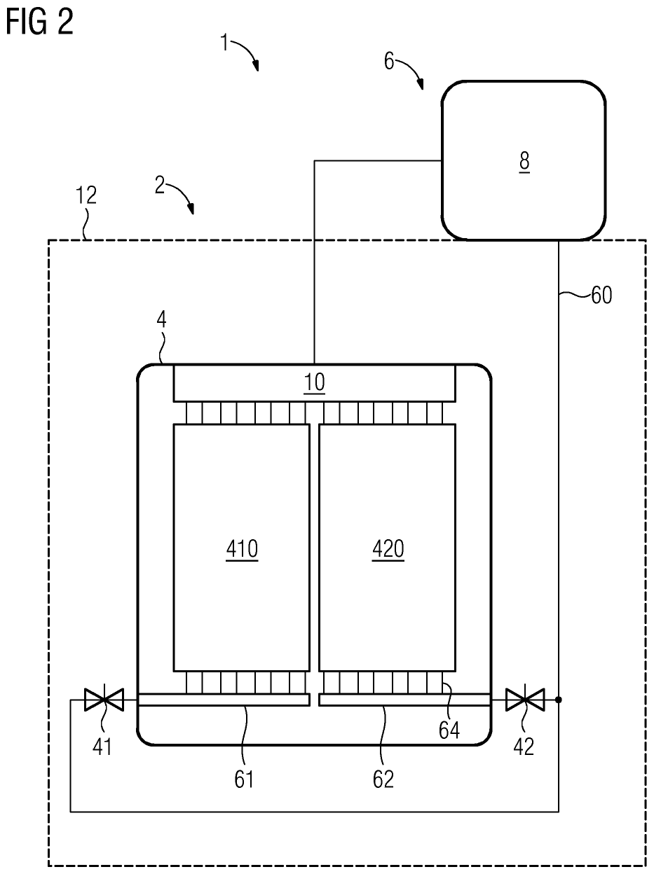

In the prior art, it is necessary to configure the cooling capacity within the cooling regions 410, 420, which are supplied by the evaporative cooling apparatus 6, to the high-loss components of the first cooling region 410. To overcome this disadvantage, FIG. 2 shows a converter with a cooling apparatus 1 in accordance with a first embodiment of the present invention.

The cooling apparatus 1 in turn comprises a condenser 8, a pipe system 60, a cooling plate 4 as well as two cooling regions 410, 420. Furthermore, a steam collector 10 is provided for collecting the evaporated cooling fluid and for guiding the evaporated cooling fluid back to the condenser 8.

As already shown in FIG. 1, the cooling apparatus 1 is arranged at least partially within a cabinet 12 of the converter 2. Typically, the condenser 8 of the evaporative cooling apparatus 6 is arranged outside the cabinet 12. As a result, the heat is emitted to the surrounding environment of the converter 2.

The cooling apparatus 1 has a first and second control element 41, 42. In this context, the control elements 41, 42 are embodied as control valves by way of example.

Furthermore, the pipe system 60 has a first line section 61 and a second line section 62. The pressure and/or mass flow of the cooling fluid within the first line section 61 can be controlled or regulated by means of the first control element 41. Similarly, the pressure and/or mass flow of the cooling fluid within the second line section 62 can be controlled or regulated by means of the second control element 42.

The teachings herein make it possible to control or regulate the cooling capacity of the evaporative cooling apparatus 6 within the first cooling region 410 and within the second cooling region 420. For instance, the cooling capacity of the evaporative cooling apparatus 6 within the first cooling region 410 is increased compared with the cooling capacity of the evaporative cooling apparatus within the second cooling region 420. In other words, the first cooling region 410 is provided for high-loss electrical components and the second cooling region 420 for low-loss electrical components of the converter 2.

To distribute the liquid cooling fluid within the cooling regions 410, 420, a plurality of fluid ducts 64 are provided. In this context, the fluid ducts 64 are in each case fluidically coupled to the associated line section 61, 62. For illustrative purposes, only one of the fluid ducts is designated with the reference character 64. The fluid ducts 64 extend approximately in parallel with one another spatially within their respective cooling region 410, 420. There may be provision for a spatially meandering extension of the cooling ducts 64 within the cooling regions 410, 420. The fluid ducts 64 extend approximately vertically in the representation in FIG. 1.

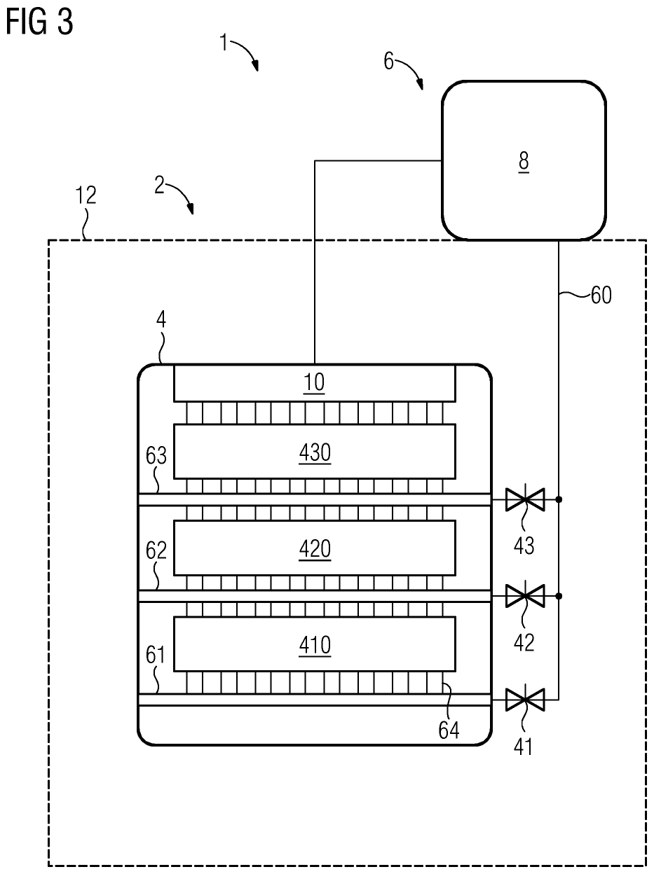

In FIG. 3, a further converter with a cooling apparatus 1 is shown in a second embodiment. The cooling apparatus 1 in FIG. 3 essentially comprises the elements of the cooling apparatus already shown in FIG. 2. In addition to FIG. 2, the cooling apparatus 1 in FIG. 3 has three cooling regions 410, 420, 430. Each of the cooling regions 410, 420, 430 is fluidically coupled to the pipe system 60 of the evaporative cooling apparatus 6 via an associated line section 61, 62, 63. To control the cooling capacity of the cooling regions 410, 420, 430, at least one control element 41, 42, 43 is provided for each line section 61, 62, 63. In this context, the control elements 41, 42, 43 are embodied as control valves and connected in parallel in relation to the cooling fluid of the evaporative cooling apparatus 6.

Furthermore, in addition to the cooling apparatus from FIG. 2, the cooling apparatus 1 has horizontally and vertically extending fluid ducts 64. In this context, the horizontal fluid ducts 64 extend at least partially between the cooling regions 410, 420, 430.

In some embodiments, it is possible to selectively control or regulate the cooling capacity within the cooling regions. In this context, the cooling regions are provided for various electrical components of a converter which are prone to losses. As a result, the energy efficiency of the cooling of a converter is improved.

Although the teachings herein have been illustrated and described in detail based on the exemplary embodiments, the scope of the teaching is not restricted by the examples given or other variations can be derived therefrom by a person skilled in the art without departing from the protective scope of the disclosure.

What is claimed is:

1. A cooling apparatus for cooling electrical components of a converter, the apparatus comprising:
a cooling plate with a first and second cooling region;
wherein a first part of the cooling plate includes the first cooling region; and
a second part of the cooling plate includes the second cooling region;
an evaporative cooler thermally coupled to both the first cooling region and the second cooling region; and
a first control element configured to adjust a cooling capacity of the evaporative cooler in relation to at least one of the two cooling regions.

2. The cooling apparatus as claimed in claim 1, further comprising a second control element configured to adjust a cooling capacity of the evaporative cooler in relation to the other cooling region.

3. The cooling apparatus as claimed in claim 1, wherein the evaporative cooler comprises a thermal pipe.

4. The cooling apparatus as claimed in claim 3, wherein the evaporative cooler includes two evaporators for evaporating a cooling fluid;
wherein the two evaporators comprises respectively the two cooling regions of the cooling plate.

5. The cooling apparatus as claimed in claim 4, wherein the evaporative cooler includes a pipe system guiding the cooling fluid;
wherein the pipe system includes a first line section for the first cooling region and a second line section for the second cooling region;
wherein a cooling capacity of the first line section is controlled by the first control element and/or a cooling capacity of the second line section is controlled by the second control element.

6. The cooling apparatus as claimed in claim 5, wherein at least one of the control elements comprises a control valve.

7. The cooling apparatus as claimed in claim 4, wherein the line sections are disposed in the cooling plate.

8. The cooling apparatus as claimed in claim 7, wherein the line sections comprise bore holes within the cooling plate.

9. The cooling apparatus as claimed in claim 5, wherein at least one of the line sections includes a plurality of fluid ducts fluidically coupled in parallel in relation to the cooling fluid;
wherein the fluid ducts extend in parallel with one another.

10. A converter comprising at least one cooling apparatus including:
a cooling plate with a first and second cooling region;
wherein a first part of the cooling plate includes the first cooling region; and
a second part of the cooling plate includes the second cooling region;
an evaporative cooler thermally coupled to both the first cooling region and the second cooling region; and
a first control element configured to adjust a cooling capacity of the evaporative cooler in relation to at least one of the two cooling regions.

11. The converter as claimed in claim 10, further comprising:
a first class and a second class of electrical components;
wherein the first class of electrical components has a higher thermal power loss than the second class of electrical components; and
the components of the first class are arranged in the first cooling region and the components of the second class in the second cooling region;
wherein the first control element can increase the cooling capacity of the evaporative cooling apparatus within the first cooling region compared to the cooling capacity of the evaporative cooling apparatus within the second cooling region.

12-14. (canceled)
